(19) United States
(12) Patent Application Publication
(10) Pub. No.: US 2026/0242978 A1
(43) Pub. Date: Aug. 20, 2026

(54) DIAMOND WAFER FABRICATION BY HETEROEPITAXY DEPOSITION

(71) Applicant: Chien-Min SUNG, New Taipei City (TW)

(72) Inventor: Chien-Min SUNG, New Taipei City (TW)

(21) Appl. No.: 19/053,629

(22) Filed: Feb. 14, 2025

(51) Int. Cl. C30B 29/04; C23C 16/02; C23C 16/27; C23C 16/455; C23C 16/50; C30B 25/10; C30B 25/16; C30B 25/18; C30B 25/20

(52) U.S. Cl. CPC C30B 29/04; C23C 16/029; C23C 16/279; C23C 16/45544; C23C 16/50; C30B 25/105; C30B 25/165; C30B 25/18; C30B 25/20

(57) ABSTRACT

A diamond film is deposited on a substrate by a heteroepitaxy deposition. The substrate is a silicon substrate or a silicon carbide substrate. During the heteroepitaxy deposition, diamond lattices of the diamond film is predominantly based on a silicon lattice of the substrate, and the diamond film has a thickness of less than 100 microns.

### FIELD OF THE INVENTION

The present invention relates to the fabrication of diamond wafers for advanced electronic and optical applications. More specifically, the invention discloses a method for producing a diamond wafer by heteroepitaxy deposition on a silicon or silicon carbide substrate.

### BACKGROUND OF THE INVENTION

Traditionally, semiconductor manufacturing has relied on the use of silicon wafers or silicon carbide wafers as the primary substrate materials. However, diamond materials, owing to their exceptional thermal conductivity, excellent electrical insulation, high mechanical strength, and superior chemical stability, are gradually receiving increasing attention as alternative wafer substrates. These unique properties make diamond particularly attractive for high-performance electronic and optical applications, where efficient heat dissipation, improved device reliability, and enhanced durability are critical. Recognizing these advantages, the present invention focuses on the development of diamond wafers, wherein diamond material itself serves as the wafer substrate. This approach departs from conventional methods that produce merely diamond films on other substrates, instead aiming to harness the full potential of diamond’s superior properties for next-generation semiconductor and related device applications.

### SUMMARY OF THE INVENTION

In view of the foregoing, it is an object of the present invention to provide a diamond film deposited on a substrate by a heteroepitaxy deposition. The substrate is a silicon substrate or a silicon carbide substrate, and diamond lattices of the diamond film is predominantly based on a silicon lattice of the substrate, and the diamond film has a thickness of less than 100 microns.

To achieve the above object, an aspect of the present invention relates to a manufacturing apparatus for producing the diamond film. The apparatus comprises a deposition chamber configured to receive a silicon substrate or a silicon carbide substrate, a substrate holder disposed within the deposition chamber, and a heating unit operable to heat the substrate to a temperature above 800℃. Gas composition during the heteroepitaxy deposition is changed so as to effect a chemical gradation from silicon or silicon carbide to carbon atoms, thereby epitaxially depositing a diamond film having diamond lattices predominantly based on the silicon lattice of the substrate and a thickness of less than 100 microns. The diamond film is formed without employing a diamond seed for nucleation.

### BRIEF DESCRIPTION OF THE DRAWINGS

Example embodiments of the present invention will be described with reference to the accompanying drawings briefly described below.

FIG. 1 shows an exemplary embodiment of the diamond film.

FIG. 2 shows an exemplary embodiment of the apparatus for producing the diamond film.

### DETAILED DESCRIPTION

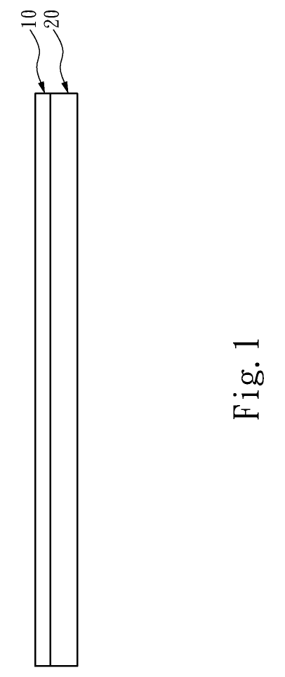

The present invention provides a method for fabricating a diamond wafer through heteroepitaxy deposition. In one example, a diamond film 10 is formed on a silicon substrate 20 or a silicon carbide substrate 20, as shown in FIG. 1. The substrate 20 with the diamond film 10 formed thereon is used as a diamond wafer. The diamond film 10 is produced by a heteroepitaxy deposition and has a thickness of less than 100 microns. During the heteroepitaxy deposition, diamond lattices of the diamond film 10 are predominantly based on the silicon lattice of the substrate 20. In some examples, the diamond film 10 itself may be used as a diamond wafer, without the substrate 20. In an example, no diamond seed is required for nucleation on the substrate 20 during the heteroepitaxy deposition. While in some examples, one or more diamond seeds are used to thicken the diamond film 10 by homoepitaxy growth.

Prior to deposition, the substrate 20 may undergo a surface pretreatment to expose the underlying silicon lattice. This pretreatment may be achieved through hydrogen plasma etching, chlorine gas or chemical etching using a solution such as potassium hydroxide (KOH). In some examples, the substrate 20 is further coated with one or more catalytic materials, for example, palladium, nickel, or iridium, which serve to promote the nucleation and growth of diamond film 10 on the substrate 20.

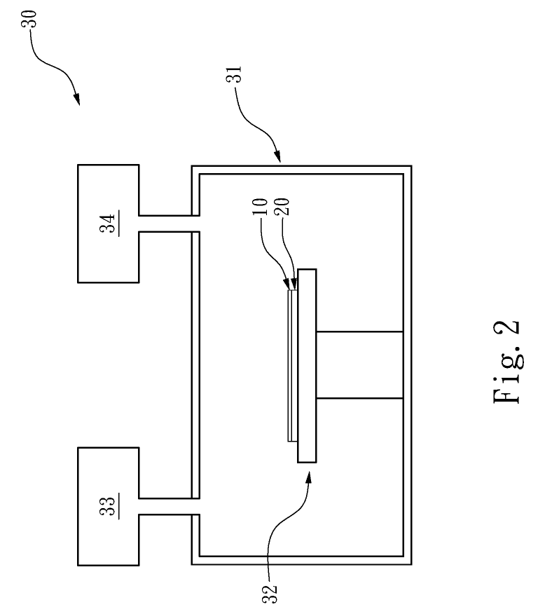

FIG. 2 illustrates an exemplary embodiment of the apparatus 30 for producing a diamond film. The apparatus 30 may be any type of deposition system capable of performing a heteroepitaxial deposition process. As shown in FIG. 2, the apparatus 30 includes a deposition chamber 31 designed to accommodate the substrate 20, a substrate holder 32 positioned within the deposition chamber 31 to support the substrate 20, a gas delivery unit 33 configured to supply purging gas, precursor, carrier gas, reactant gas, and other gases required for the heteroepitaxial deposition process, and a heating unit 34 capable of heating the substrate 20 to a temperature exceeding 800°C.

Following the pretreatment, the heteroepitaxy deposition process in which the diamond film 10 is formed through a controlled chemical gradation. In the process, the initial gas atmosphere in the deposition chamber is tailored to favor the presence of silicon compounds, and then gradually adjusted to favor the formation of carbon compounds. Typically, an Atomic Layer Deposition (ALD) apparatus is used, wherein a gas mixture comprising hydrogen, silane, and methane is introduced into the chamber. During deposition, the ratio of silane to methane is slowly decreased, thereby effecting a chemical transformation of the silicon lattice of the substrate 20 into a diamond lattice. This results in the epitaxial growth of the diamond film 10 whose crystalline structure is predominantly based on the underlying silicon lattice of the substrate 20, yet exhibits the superior material properties of diamond. In other examples, the apparatus may be a molecular beam epitaxy system, a metal-organic chemical vapor deposition system, a physical vapor deposition system, a liquid phase epitaxy system or a chemical vapor deposition system.

The deposition process may be performed under vacuum conditions and at high temperatures—generally above 800℃, with embodiments operating at approximately 900℃—to ensure proper diamond formation. The plasma required for the deposition is generated by either an Electron Cyclotron Resonance (ECR) array or a Remote Plasma Supply (RPS). In one preferred embodiment, an eight-inch silicon wafer (with a (100) crystallographic orientation) is positioned within the ALD chamber and exposed to hydrogen plasma generated by an ECR array positioned above the wafer. The gas mixture, diluted to about 1% in hydrogen (which also functions as a purging gas), is introduced, and the controlled reduction of the silane-to-methane ratio gradually effects the chemical gradation necessary to form the diamond wafer. Alternatively, the invention contemplates a similar process wherein the plasma is generated by a Remote Plasma Supply (RPS) rather than an ECR array.

In another embodiment, the process is modified by replacing the gas mixture of silane and methane with silicon tetrachloride (SiCl₄) and carbon tetrachloride (CCl₄), while the purging gas is substituted with chlorine (Cl₂) gas. This alternative gas chemistry further demonstrates the adaptability of the chemical gradation approach in producing a high-quality diamond wafer. The final diamond wafer produced by this method is characterized by a thickness of less than 100 microns and a top surface substantially free of grain boundaries, attributes which render the wafer particularly well-suited for integration into semiconductor devices, light-emitting diodes (LEDs), surface acoustic wave (SAW) filters, heat spreaders, gem diamonds, or tweeter diaphragms. In an exemplary embodiment, the thickness of the diamond wafer may have the thickness between 10 microns and 80 microns, for example, between 30 microns and 60 microns.

To illustrate the invention further, the following examples are provided.

### Example 1:

An eight-inch silicon wafer with a (100) orientation is first placed in an ALD system. The wafer is subjected to hydrogen plasma etching under vacuum conditions, with the plasma generated by an Electron Cyclotron Resonance (ECR) array positioned above the wafer. The wafer is then heated to a temperature of 900℃. A gas mixture comprising hydrogen, silane, and methane is introduced into the chamber. Initially, the gas mixture is adjusted to favor the presence of silane, and over time the ratio of silane to methane is gradually decreased. This controlled reduction in the silane-to-methane ratio induces a chemical gradation from silicon to carbon, thereby facilitating the epitaxial formation of a diamond wafer on the silicon lattice of the substrate. The gas mixture is maintained at a dilution of 1% in hydrogen, which may also serves as the purging gas.

### Example 2:

In this embodiment, the process follows that of Example 1 with one modification: the plasma is generated using a Remote Plasma Supply (RPS) rather than an ECR array. All other process parameters—including substrate pretreatment, temperature, and gas composition—remain the same, resulting in the formation of a diamond wafer with similar characteristics.

### Example 3:

In an alternative embodiment, the gas mixture of silane and methane is replaced by a mixture of silicon tetrachloride (SiCl₄) and carbon tetrachloride (CCl₄). The gas mixture of silicon tetrachloride and carbon tetrachloride is the precursor for the ALD. Additionally, the purging gas is substituted with chlorine (Cl₂) gas. The precursor and the purging gas are alternatively introduced into the chamber to achieve the heteroepitaxy deposition. With the substrate pretreated as described and maintained at a temperature above 800℃, the chemical gradation process proceeds in a similar manner to yield an epitaxial diamond wafer with a crystalline structure predominantly aligned with the silicon lattice of the substrate.

Unlike conventional semiconductor technology that predominantly utilizes silicon or silicon carbide wafers, this invention focuses on employing diamond material as the wafer substrate to exploit its superior thermal, electrical, mechanical, and chemical properties

1. A diamond film deposited on a substrate by a heteroepitaxy deposition, wherein the substrate is a silicon substrate or a silicon carbide substrate, and wherein diamond lattices of the diamond film are predominantly based on a silicon lattice of the substrate, and the diamond film has a thickness of less than 100 microns.

2. The diamond film of claim 1, wherein there is no diamond seed for nucleation on the substrate during the heteroepitaxy deposition.

3. The diamond film of claim 1, wherein one or more diamond seeds are used to thicken the diamond film by homoepitaxy growth.

4. The diamond film of claim 1, wherein formation of the diamond film is achieved through chemical gradation from silicon or silicon carbide to carbon atoms.

5. The diamond film of claim 4, wherein atomic layer deposition is used to achieve the chemical gradation from silicon or silicon carbide to diamond.

6. The diamond film of claim 1, wherein the heteroepitaxy deposition employs an electron cyclotron resonance array to generate plasma comprising hydrogen mixed with silane and/or methane.

7. The diamond film of claim 1, wherein the heteroepitaxy deposition employs a remote plasma supply to generate plasma comprising hydrogen mixed with silane and/or methane.

8. The diamond film of claim 1, wherein the heteroepitaxy deposition is performed at a temperature above 800℃.

9. The diamond film of claim 1, wherein the substrate is coated with one or more catalytic materials.

10. The diamond film of claim 9, wherein the catalytic material is palladium, nickel, iridium or a combination thereof.

11. The diamond film of claim 1, wherein a surface pretreatment is carried out on the substrate prior to the heteroepitaxy deposition to expose the silicon lattice of the substrate.

12. The diamond film of claim 11, wherein the surface pretreatment is hydrogen plasma etching, chlorine gas or chemical etching using KOH.

13. The diamond film of claim 1, wherein a top surface of the diamond film is substantially free of grain boundaries.

14. The diamond film of claim 1, wherein the diamond film is configured for applications including semiconductors, light-emitting diodes, surface acoustic wave filters, heat spreaders, gem diamonds or tweeter diaphragms.

15. The diamond film of claim 1, wherein a precursor and a purging gas are introduced during the heteroepitaxy deposition, and wherein the precursor is a gas mixture of silicon tetrachloride and carbon tetrachloride, and wherein the purging gas is chlorine gas.

16. A manufacturing apparatus for producing a diamond film of claim 1, the apparatus comprising:
a deposition chamber configured to receive a silicon substrate or a silicon carbide substrate;
a substrate holder disposed within the deposition chamber; and
a heating unit operable to heat the substrate to a temperature above 800℃;
wherein gas composition during the heteroepitaxy deposition is changed so as to effect a chemical gradation from silicon or silicon carbide to carbon atoms, thereby epitaxially depositing a diamond film having diamond lattices predominantly based on the silicon lattice of the substrate and a thickness of less than 100 microns; and
wherein the diamond film is formed without employing a diamond seed for nucleation.

17. The manufacturing apparatus of claim 15, wherein a precursor and a purging gas are introduced during the heteroepitaxy deposition, and wherein the precursor is a gas mixture of silicon tetrachloride and carbon tetrachloride, and wherein the purging gas is chlorine gas.
